(19) United States
(12) Patent Application Publication
(10) Pub. No.: US 2021/0408063 A1
(43) Pub. Date: Dec. 30, 2021

(54) ARRAY SUBSTRATE AND METHOD OF MANUFACTURING SAME

(71) Applicant: WUHAN CHINA STAR OPTOELECTRONICS SEMICONDUCTOR DISPLAY TECHNOLOGY CO., LTD., WUHAN, HUBEI (CN)

(72) Inventor: CHENGZHI LUO, WUHAN, HUBEI (CN)

(21) Appl. No.: 16/756,147

(22) PCT Filed: Feb. 19, 2020
(86) PCT No.: PCT/CN2020/075798

§ 371 Date: Apr. 15, 2020

(30) Foreign Application Priority Data
Dec. 19, 2019 (CN) 201911316965.0

(51) Int. Cl. H01L 27/12

(52) U.S. Cl. CPC H01L 27/1218; H01L 27/1262; H01L 27/1288

(57) ABSTRACT

An array substrate and a method of manufacturing the same are provided. The array substrate includes a base substrate, a buffer layer, an active layer, a dielectric insulating layer, and a source/drain layer stacked in sequence. A trench is provided on a surface of the base substrate facing the buffer layer, and the trench is sunk to another surface of the base substrate. The array substrate further includes a gate layer. The gate layer is disposed in the trench of the base substrate. The buffer layer is disposed on the base substrate and totally covers the gate layer.

### FIELD

The present disclosure relates to display technologies, and more particularly, to an array substrate and a method of manufacturing the same.

### BACKGROUND

Thin film transistor liquid crystal displays (TFT-LCDs) have advantages of low power consumption, high contrast, and space saving, and have become the most mainstream display devices on market. Compared with traditional amorphous silicon (A-Si) technology, low temperature polysilicon (LTPS) technology has higher carrier mobility and is widely used in production of small and medium-sized high-resolution thin film transistor liquid crystal displays and active matrix organic light-emitting devices (AMOLED). But number of photomasks required for corresponding array substrate production is larger, and a product manufacturing cycle is longer. How to effectively reduce the manufacturing cycle of low-temperature polysilicon array substrates, increase production capacity and reduce costs, thereby increasing company's market competitiveness, is a focus of current panel industry. An effective way to improve this issue is to develop a new low-temperature polysilicon array substrate structure with reduced number of photomasks required for array production.

In traditional low-temperature polysilicon array substrate technology, a top gate plus light shield layer (LS) structure is usually used. The preparation of the light-shielding layer requires an additional LS mask to form an opaque pattern under a channel of the array substrate. It is mainly used in panel to block backlight from directly illuminating the channel of the array substrate and cause photo-induced leakage current. Excessive leakage current will significantly affect the optical display effect of the product, such as crosstalk, flicker, and contrast, etc. Therefore, how to effectively reduce the photo- induced leakage current through the improvement of the device structure base on eliminating the LS mask, reducing the product manufacturing cycle and reducing the production cost is an important content of the low-temperature polysilicon array substrate technology development.

At present, there is a solution that uses an array substrate with a bottom gate structure. A gate line can function as a light shielding layer and as a gate, so that a LS mask can be saved. However, because the gate line is thicker, the low temperature polysilicon will be broken at a climbing edge of the gate line, which will affect the electrical properties.

Therefore, it is necessary to develop a new type of array substrate and a manufacturing method thereof to overcome the defects in the prior art.

### SUMMARY

In view of the above, the present disclosure provides an array substrate and a method of manufacturing the same to provide a bottom gate structure to save a mask when manufacturing the array substrate, and reduce numbers of the photomask. It is no need to provide a light shielded layer, so a production process is simplifying, production efficiency is improved, production time is saved, cost is reduced, and the low temperature polysilicon broken at a climbing edge of the gate line is avoided to improve yield.

In order to achieve above-mentioned object of the present disclosure, one embodiment of the disclosure provides an array substrate including a base substrate, a buffer layer, an active layer, a dielectric insulating layer, and a source/drain layer stacked in sequence. A trench is provided on a surface of the base substrate facing the buffer layer, the trench is sunk to another surface of the base substrate. The array substrate further includes a gate layer. The gate layer is disposed in the trench of the base substrate. The buffer layer is disposed on the base substrate and totally covers the gate layer. The active layer is disposed on the buffer layer and provided with a channel region and doping regions disposed at opposite ends of the channel region. The dielectric insulating layer is disposed on the active layer. The source/drain layer is disposed on the dielectric insulating layer and electrically connected to the doping regions.

In one embodiment of the array substrate, the channel region is disposed totally corresponding to the gate layer.

In one embodiment of the array substrate, a depth of the trench is equal to a thickness of the gate layer plus or minus 20 nm.

In one embodiment of the array substrate, the doping regions include first doping regions and second doping regions. The first doping regions are disposed at opposite ends of the channel region. The first doping regions are doped with high concentration of phosphorous ions. The second doping regions are disposed between the channel region and the first doping regions. The second doping regions are doped with low concentration of phosphorous ions.

In one embodiment of the array substrate, the buffer layer includes a first buffer layer and a second buffer layer. The first buffer layer is disposed on the base substrate and totally covers the gate layer. The second buffer layer is disposed on the first buffer layer. The active layer is disposed on the second buffer layer.

In one embodiment of the array substrate, the dielectric insulating layer includes a first insulating layer and a second insulating layer. The first insulating layer is disposed on the buffer layer and totally covers the active layer. The second insulating layer is disposed on the first insulating layer. The source/drain layer is disposed on the second insulating layer.

Another embodiment of the disclosure provides a method of manufacturing an array substrate, including steps of:

providing a base substrate, coating a negative photoresist on the base substrate, and exposing and developing the negative photoresist with a first photomask to form a through hole pattern;

dry etching the base substrate to form a trench, wherein a depth of the trench is equal to a thickness of a prefabricated gate layer plus or minus 20 nm;

providing a gate layer by physical vapor deposition, wherein the gate layer is fill up the trench;

peeling the negative photoresist from the base substrate and providing a buffer layer on the base substrate;

depositing amorphous silicon on the buffer layer, annealing the amorphous silicon by a laser to form a polycrystalline silicon, and forming an active layer pattern by exposure, development, and etching;

doping two opposite ends of the active layer to form a channel region and doping regions at opposite ends of the channel region;

providing a dielectric insulating layer on the active layer; and

providing a source/drain layer on the dielectric insulating layer, wherein the source/drain layer is electrically connected to the doping regions.

In one embodiment of the method of manufacturing the array substrate, the step of providing the buffer layer further includes steps of:

providing a first buffer layer on the base substrate by a SiNx deposition; and

providing a second buffer layer on the first buffer layer by a SiOx deposition.

In one embodiment of the method of manufacturing the array substrate, the step of doping two opposite ends of the active layer further includes steps of:

providing a photoresist layer on the active layer;

etching the photoresist layer with a second photomask to form first doping regions, wherein the first doping regions are disposed at opposite ends of the active layer and doped with high concentration of phosphorous ions;

etching the photoresist layer by an etching machine to reduce a width of the photoresist layer and form second doping regions, wherein the second doping regions are disposed between the channel region and the first doping regions and doped with low concentration of phosphorous ions;

peeling the photoresist layer from the active layer.

In one embodiment of the method of manufacturing the array substrate, the step of providing the dielectric insulating layer further includes steps of:

providing a first insulating layer on the buffer layer by a SiNx deposition; and

providing a second insulating layer on the first insulating layer by a SiOx deposition.

In comparison with prior art, the array substrate and the method of manufacturing the same provide a bottom gate structure to save a mask when manufacturing the array substrate, and reduce numbers of the photomask. It is no need to provide a light shielded layer, so a production process is simplifying, production efficiency is improved, production time is saved, cost is reduced, and the low temperature polysilicon broken at a climbing edge of the gate line is avoided to improve yield.

### BRIEF DESCRIPTION OF DRAWINGS

FIG. 1 is a schematic view of a structure of an array substrate according to an embodiment of the present disclosure.

FIG. 2 is a schematic flowchart of a manufacturing method of an array substrate according to an embodiment of the present disclosure.

FIG. 3 is a schematic view of a structure of a semi-finished product after finished a gate layer 2.

FIG. 4 is a schematic view of a structure of a semi-finished product after finished an active layer 4.

FIG. 5 is a schematic view of a structure of a semi-finished product after finished first doping regions 421.

FIG. 6 is a schematic view of a structure of a semi-finished product after finished second doping regions 422.

FIG. 7 is a schematic flowchart of a step of providing a buffer layer in step S4 of FIG. 2.

FIG. 8 is a schematic flowchart of a step of doping two opposite ends of the active layer in step S6 of FIG. 2.

FIG. 9 is a schematic flowchart of a step of providing a dielectric insulating layer in step S8 of FIG. 2.

Reference numbers of the present disclosure are as follows:

1: base substrate, 2: gate layer, 3: Buffer layer, 4: active layer, 5: dielectric insulating layer, 6: source/drain layer, 7: negative photoresist, 8: photoresist layer, 11: trench, 31: first buffer layer, 32: second buffer layer, 41: channel region, 42: doping region, 51: first insulating layer, 52: second insulating layer, 61: source, 62: drain, 100: array substrate, 421: first doping region, 422: second doping region.

### DETAILED DESCRIPTION

The following description of the embodiments is provided by reference to the drawings and illustrates the specific embodiments of the present disclosure. Directional terms mentioned in the present disclosure, such as “up,” “down,” “top,” “bottom,” “forward,” “backward,” “left,” “right,” “inside,” “outside,” “side,” “peripheral,” “central,” “horizontal,” “peripheral,” “vertical,” “longitudinal,” “axial,” “radial,” “uppermost” or “lowermost,” etc., are merely indicated the direction of the drawings. Therefore, the directional terms are used for illustrating and understanding of the application rather than limiting thereof.

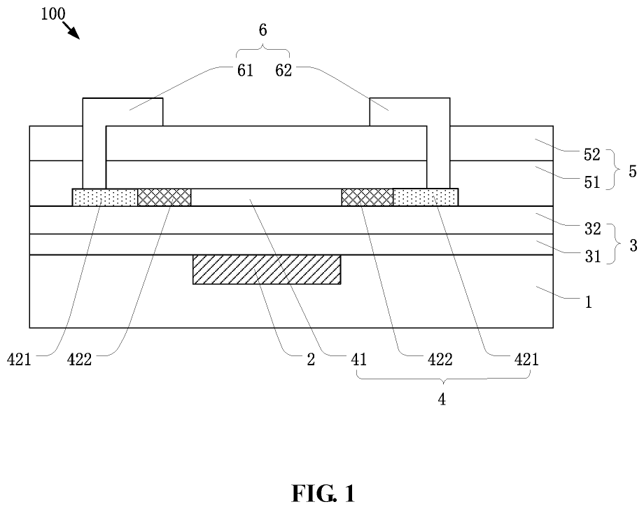

In detail, referring to FIG. 1, one embodiment of the disclosure provides an array substrate 100 including a base substrate 1, a buffer layer 3, an active layer 4, a dielectric insulating layer 5, and a source/drain layer 6 stacked in sequence. The base substrate 1 is a bare glass substrate. A trench 11 is provided on a surface of the base substrate 1 facing the buffer layer 3, the trench 11 is sunk to another surface of the base substrate 1. The array substrate 100 further includes a gate layer 2. The gate layer 2 is disposed in the trench 11 of the base substrate 1. The buffer layer 3 is disposed on the base substrate 1 and totally covers the gate layer 2. The active layer 4 is disposed on the buffer layer 3 and provided with a channel region 41 and doping regions 42 disposed at opposite ends of the channel region 41. The dielectric insulating layer 5 is disposed on the active layer 4. The source/drain layer 6 is disposed on the dielectric insulating layer 5 and electrically connected to the doping regions 42.

The disclosure provides a bottom gate structure to dispose the gate layer 2 in the trench 11 of the base substrate 1 to avoid the active layer 4 with a low temperature polysilicon material from broken at a climbing edge of the gate layer 2 and to improve yield.

In the embodiment, the channel region 41 is disposed totally corresponding to the gate layer 2. The gate layer 2 can be a gate and function as a light shielding layer (LS), so that a LS can be saved. It is no need to provide a light shielded layer and reduce numbers of the photomask to improve production efficiency.

In one embodiment of the array substrate, a depth of the trench 11 is equal to a thickness of the gate layer 2 plus or minus 20 nm. The depth of the trench 11 is preferred equal to a thickness of the gate layer 2. Such that the gate layer 2 can fill up the trench 11. An upper surface of the gate layer 2 meets an upper surface of the base substrate 1 to avoid a climbing edge of the active layer 4 disposed on the gate layer 2, ensure a flatness of the active layer 4, avoid the active layer 4 from broken, and improve product yield.

In one embodiment of the array substrate, the doping regions 42 include first doping regions 421 and second doping regions 422. The first doping regions 421 are disposed at opposite ends of the channel region 41. The first doping regions 421 are N+ doping regions doped with high concentration of phosphorous ions. A high concentration Phosphorous ions dopant is a light dopant. The second doping regions 422 are disposed between the channel region 41 and the first doping regions 421. The second doping regions 422 are N− doping regions doped with low concentration of phosphorous ions.

In detail, the source/drain layer 6 includes source 61 and drain 62 electrically connected to the first doping regions 421 respectively at two opposite ends of the channel region 41.

In one embodiment of the array substrate, the buffer layer 3 includes a first buffer layer 31 and a second buffer layer 32. The first buffer layer 31 is disposed on the base substrate 1 and totally covers the gate layer 2. A material of the first buffer layer 31 includes a SiNx. The second buffer layer 32 is disposed on the first buffer layer 31. The active layer 4 is disposed on the second buffer layer 32. A material of the second buffer 32 includes a SiOx.

In one embodiment of the array substrate, the dielectric insulating layer 5 includes a first insulating layer 51 and a second insulating layer 52. The first insulating layer 51 is disposed on the buffer layer 3 and totally covers the active layer 4. A material of the first insulating layer 51 includes a SiNx. The second insulating layer 52 is disposed on the first insulating layer 51. The source/drain layer 6 is disposed on the second insulating layer 52. A material of the second insulating layer includes a SiOx.

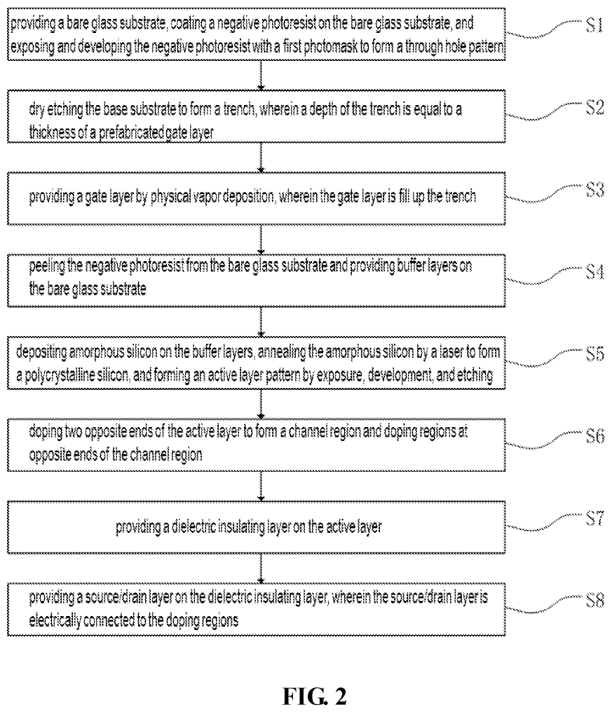

Referring to FIG. 2, another embodiment of the disclosure provides a method of manufacturing an array substrate 100, including steps of:

At step S1: providing a base substrate 1, coating a negative photoresist 7 on the base substrate 1, and exposing and developing the negative photoresist with a first photomask to form a through hole pattern. Due to characteristics of the negative photoresist 7, an undercut structure is generated. A cross-section of the etched through hole is rectangular or inverted trapezoid, which is convenient for subsequent fabrication of the gate layer 2 by physical vapor deposition.

At step S2: dry etching the base substrate 1 to form a trench 11, wherein a depth of the trench 11 is equal to a thickness of a prefabricated gate layer 2 plus or minus 20 nm.

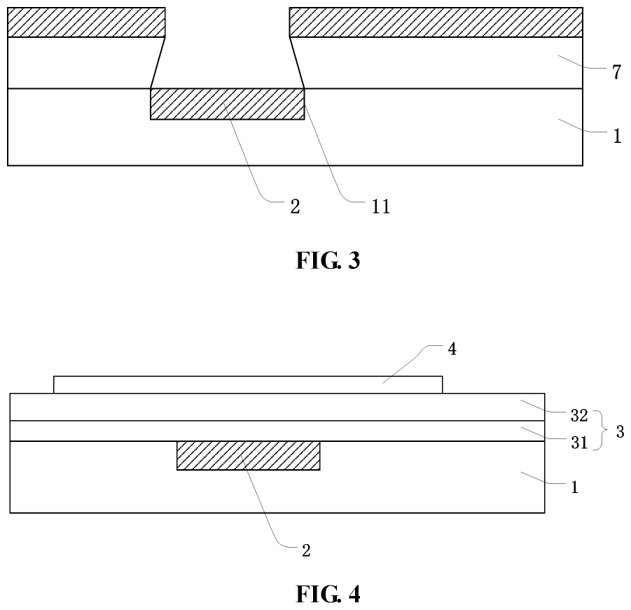

At step S3: providing a gate layer 2 by physical vapor deposition, wherein the gate layer 2 is fill up the trench 11 to make the upper surface of the gate layer 2 meet an upper surface of the base substrate 1. FIG. 3 is a schematic view of a structure of a semi-finished product after finished the gate layer 2.

At step S4: peeling the negative photoresist 7 from the base substrate 1 and providing a buffer layer 3 on the base substrate;

At step S5: depositing amorphous silicon on the buffer layer 3, annealing the amorphous silicon by a laser to form a polycrystalline silicon, and forming a pattern of the active layer 4 by exposure, development, and etching. FIG. 4 is a schematic view of a structure of a semi-finished product after finished an active layer 4.

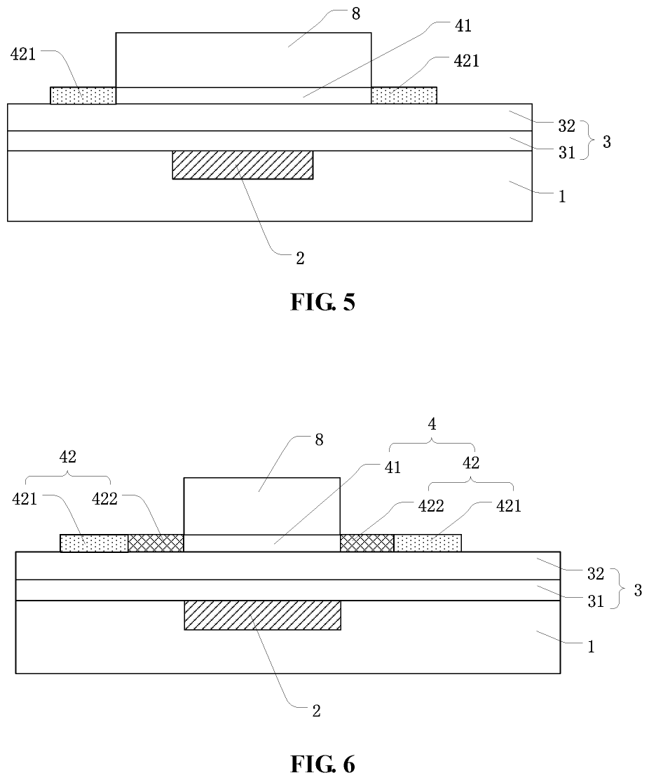

At step S6: doping two opposite ends of the active layer 4 to form a channel region 41 and doping regions 42 at opposite ends of the channel region 41. The processes are shown in FIG. 5 and FIG. 6.

At step S7: providing a dielectric insulating layer 5 on the active layer 4; and

At step S8: providing a source/drain layer 6 on the dielectric insulating layer 5, wherein the source/drain layer 6 is electrically connected to the doping regions 42.

FIG. 1 is a schematic view of a structure of a finished array substrate 100.

The embodiment of the disclosure provides a bottom gate structure to dispose the gate layer 2 in the trench 11 of the base substrate 1 to avoid the active layer 4 with a low temperature polysilicon material from broken at a climbing edge of the gate layer 2 and to improve yield. The depth of the trench 11 is preferred equal to a thickness of the gate layer 2 in step S2. Such that the gate layer 2 can fill up the trench 11. An upper surface of the gate layer 2 meets an upper surface of the base substrate 1 to avoid a climbing edge of the active layer 4 disposed on the gate layer 2, ensure a flatness of the active layer 4, avoid the active layer 4 from broken, and improve product yield.

In the embodiment, the channel region 41 is disposed totally corresponding to the gate layer 2. The gate layer 2 can be a gate and function as a light shielding layer (LS), so that a LS can be saved. It is no need to provide a light shielded layer, reduce a photomask in process and reduce numbers of the photomask to improve production efficiency.

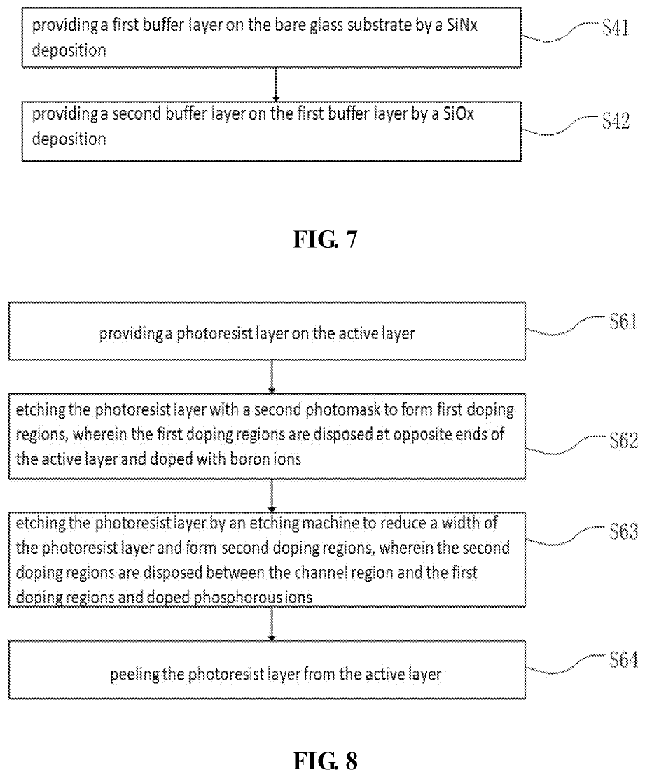

Referring to FIG. 7, in one embodiment of the method of manufacturing the array substrate, the step S4 of providing the buffer layer 3 further includes steps of:

At step S41: providing a first buffer layer 31 on the base substrate 1 by a SiNx deposition; and

At step S42: providing a second buffer layer 32 on the first buffer layer 31 by a SiOx deposition.

Referring to FIG. 8, in one embodiment of the method of manufacturing the array substrate, the step S6 of doping two opposite ends of the active layer 4 further includes steps of:

At step S61: providing a photoresist layer 8 on the active layer 4;

At step S62: etching the photoresist layer 8 with a second photomask to form first doping regions 421, wherein the first doping regions 421 are disposed at opposite ends of the active layer 4 and doped with high concentration of phosphorous ions. The first doping regions 421 after doping are N+ doping regions. FIG. 5 is a schematic view of a structure of a semi-finished product after finished first doping regions 421.

At step S63: etching the photoresist layer 8 by an etching machine to reduce a width of the photoresist layer 8 and form second doping regions 422, wherein the second doping regions 422 are disposed between the channel region 41 and the first doping regions 421 and doped with low concentration of phosphorous ions. The second doping regions 422 after doping are N− doping regions. FIG. 6 is a schematic view of a structure of a semi-finished product after finished second doping regions 422.

At step S64: peeling the photoresist layer 8 from the active layer 4.

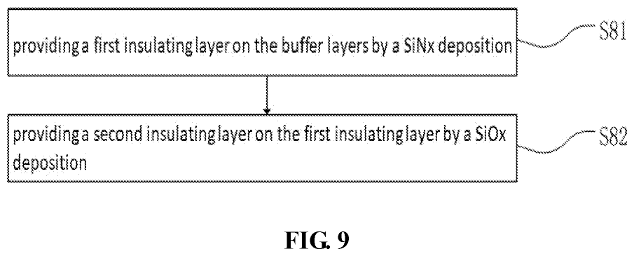

Referring to FIG. 9, in one embodiment of the method of manufacturing the array substrate, the step S8 of providing the dielectric insulating layer 5 further includes steps of:

At step S81: providing a first insulating layer 51 on the buffer layer 3 by a SiNx deposition; and

At step S82: providing a second insulating layer 52 on the first insulating layer 51 by a SiOx deposition.

In comparison with prior art, the array substrate 100 and the method of manufacturing the same provide a bottom gate structure to save a mask when manufacturing the array substrate 100, and reduce numbers of the photomask. It is no need to provide a light shielded layer, so a production process is simplifying, production efficiency is improved, production time is saved, cost is reduced, and the low temperature polysilicon broken at a climbing edge of the gate line is avoided to improve yield.

The present disclosure has been described by the above embodiments, but the embodiments are merely examples for implementing the present disclosure. It must be noted that the embodiments do not limit the scope of the invention. In contrast, modifications and equivalent arrangements are intended to be included within the scope of the invention.

What is claimed is:

1. An array substrate, comprising a base substrate, a buffer layer, an active layer, a dielectric insulating layer, and a source/drain layer stacked in sequence, wherein
a trench is provided on a surface of the base substrate facing the buffer layer, the trench is sunk to another surface of the base substrate, and the array substrate further comprises a gate layer, the gate layer is disposed in the trench of the base substrate, and the buffer layer is disposed on the base substrate and totally covers the gate layer; and
the active layer is disposed on the buffer layer and provided with a channel region and doping regions disposed at opposite ends of the channel region, the dielectric insulating layer is disposed on the active layer, and the source/drain layer is disposed on the dielectric insulating layer and electrically connected to the doping regions.

2. The array substrate according to claim 1, wherein the channel region is disposed corresponding to the gate layer.

3. The array substrate according to claim 1, wherein a depth of the trench is equal to a thickness of the gate layer plus or minus 20 nm.

4. The array substrate according to claim 1, wherein the doping regions comprise:
first doping regions disposed at opposite ends of the channel region, wherein the first doping regions are doped with high concentration of phosphorous ions; and
second doping regions disposed between the channel region and the first doping regions, wherein the second doping regions are doped with low concentration of phosphorous ions.

5. The array substrate according to claim 1, wherein the buffer layer comprises:
a first buffer layer disposed on the base substrate and totally covering the gate layer; and
a second buffer layer disposed on the first buffer layer, wherein the active layer is disposed on the second buffer layer.

6. The array substrate according to claim 1, wherein the dielectric insulating layer comprises:
a first insulating layer disposed on the buffer layer and totally covering the active layer; and
a second insulating layer disposed on the first insulating layer, wherein the source/drain layer is disposed on the second insulating layer.

7. A method of manufacturing an array substrate, comprising steps of:
providing a base substrate, coating a negative photoresist on the base substrate, and exposing and developing the negative photoresist with a first photomask to form a through hole pattern;
dry etching the base substrate to form a trench, wherein a depth of the trench is equal to a thickness of a prefabricated gate layer plus or minus 20 nm;
providing a gate layer by physical vapor deposition, wherein the gate layer is fill up the trench;
peeling the negative photoresist from the base substrate and providing a buffer layer on the base substrate;
depositing amorphous silicon on the buffer layer, annealing the amorphous silicon by a laser to form a polycrystalline silicon, and forming an active layer pattern by exposure, development, and etching;
doping two opposite ends of the active layer to form a channel region and doping regions at opposite ends of the channel region;
providing a dielectric insulating layer on the active layer; and
providing a source/drain layer on the dielectric insulating layer, wherein the source/drain layer is electrically connected to the doping region.

8. The method of manufacturing the array substrate according to claim 7, wherein the step of providing the buffer layer further comprises steps of:
providing a first buffer layer on the base substrate by a SiNx deposition; and
providing a second buffer layer on the first buffer layer by a SiOx deposition.

9. The method of manufacturing the array substrate according to claim 7, wherein the step of doping two opposite ends of the active layer further comprises steps of:
providing a photoresist layer on the active layer;
etching the photoresist layer with a second photomask to form first doping regions, wherein the first doping regions are disposed at opposite ends of the active layer and doped with high concentration of phosphorous ions;
etching the photoresist layer by an etching machine to reduce a width of the photoresist layer and form second doping regions, wherein the second doping regions are disposed between the channel region and the first doping regions and doped with low concentration of phosphorous ions;
peeling the photoresist layer from the active layer.

10. The method of manufacturing the array substrate according to claim 7, wherein the step of providing the dielectric insulating layer further comprises steps of:
providing a first insulating layer on the buffer layer by a SiNx deposition; and
providing a second insulating layer on the first insulating layer by a SiOx deposition.
